(19) United States
(12) Patent Application Publication
(10) Pub. No.: US 2026/0353687 A1
(43) Pub. Date: Nov. 5, 2026

(54) INSULATED GATE BIPOLAR TRANSISTOR

(71) Applicant: Samsung Electronics Co., Ltd., Suwon-si (KR)

(72) Inventors: Young Jun Byun, Suwon-si (KR); Jonghak Kim, Suwon-si (KR); Sung-Won You, Suwon-si (KR); Heeseung Yoon, Suwon-si (KR)

(21) Appl. No.: 19/414,682

(22) Filed: Dec. 10, 2025

(30) Foreign Application Priority Data
Mar. 4, 2025 (KR) 10-2025-0027412

(51) Int. Cl. H10D 12/00; H10D 12/01; H10D 62/13; H10D 62/832

(52) U.S. Cl. CPC H10D 12/481; H10D 12/038; H10D 62/137; H10D 62/8325

(57) ABSTRACT

The semiconductor device includes a collector electrode, a first semiconductor layer of a first conductivity type stacked on the collector electrode, a second semiconductor layer of a second conductivity type, a first well region of the first conductivity type, and a second well region of the second conductivity type, an emitter electrode positioned on the second well region, a gate electrode adjacent to the first well region, a gate insulating layer positioned between the gate electrode and the first well region, and a first tunneling layer positioned between the collector electrode and the first semiconductor layer. The first tunneling layer is a semiconductor layer of the second conductivity type and is thinner than the first semiconductor layer.

### CROSS-REFERENCE TO RELATED APPLICATION

This application claims priority to and the benefit of Korean Patent Application No. 10-2025-0027412 filed with the Korean Patent Office on Mar. 4, 2025, the entire contents of which are incorporated herein by reference.

### TECHNICAL FIELD

The present disclosure relates to a semiconductor device.

### BACKGROUND

An insulated gate bipolar transistor (IGBT) has a structure that combines a bipolar junction transistor (BJT) and a metal-oxide-semiconductor field effect transistor (MOSFET). IGBTs may have desired current driving capability of BJTs and switching characteristics of MOSFETs due to their insulated gates. IGBTs may be used as devices for controlling high voltages and high currents, for example, power devices.

### SUMMARY

The embodiments are for implementing an ohmic contact between a p-type semiconductor layer and an electrode of a semiconductor device using a semiconductor material having a high energy band gap.

According to an aspect of the disclosure, a semiconductor device comprises a collector electrode, a first semiconductor layer of a first conductivity type, a second semiconductor layer of a second conductivity type, a first well region of the first conductivity type, and a second well region of the second conductivity type, which stacked on the collector electrode, an emitter electrode on the second well region, a gate electrode adjacent to the first well region, a gate insulating layer between the gate electrode and the first well region, and a first tunneling layer between the collector electrode and the first semiconductor layer, wherein the first tunneling layer is a semiconductor layer of the second conductivity type and is thinner than the first semiconductor layer.

According to another aspect of the disclosure, a semiconductor device comprises a collector electrode, a first semiconductor layer of a first conductivity type, a second semiconductor layer of a second conductivity type, a first well region of the first conductivity type, and a second well region of the second conductivity type, which stacked on the collector electrode, an emitter electrode on the second well region, a gate electrode adjacent to the first well region, a gate insulating layer between the gate electrode and the first well region, and a first tunneling layer between the collector electrode and the first semiconductor layer, wherein the first tunneling layer is a semiconductor layer of the first conductivity type and includes a semiconductor material having a smaller energy band gap than a semiconductor material of the first semiconductor layer.

According to another aspect of the disclosure, a semiconductor device comprises a collector electrode, a first semiconductor layer of a first conductivity type, a second semiconductor layer of a second conductivity type, a first well region of the first conductivity type, and a second well region of the second conductivity type, which stacked on the collector electrode, an emitter electrode on the second well region, a gate electrode adjacent to the first well region, a gate insulating layer between the gate electrode and the first well region, and a first tunneling layer and a second tunneling layer between the collector electrode and the first semiconductor layer, wherein the first tunneling layer is on the collector electrode, the second tunneling layer is on the first tunneling layer, the first semiconductor layer is on the second tunneling layer, and wherein an energy band gap of the first tunneling layer and an energy band gap of the second tunneling layer are different.

According to embodiments, an ohmic contact between a p-type semiconductor layer and an electrode of a semiconductor device using a semiconductor material having a high energy band gap may be implemented.

### BRIEF DESCRIPTION OF THE DRAWINGS

FIG. 1 is a cross-sectional view of a semiconductor device according to some embodiments.

FIG. 2 is an energy band diagram of a cross-section taken along line A-A′ of FIG. 1.

FIG. 3 is a cross-sectional view of a semiconductor device according to some embodiments.

FIG. 4 is a cross-sectional view of a semiconductor device according to some embodiments.

FIG. 5 is an energy band diagram of a cross-section taken along line B-B′ of FIG. 4.

FIG. 6 is a cross-sectional view of a semiconductor device according to some embodiments.

FIG. 7 is a cross-sectional view of a semiconductor device according to some embodiments.

FIG. 8 is an energy band diagram of a cross-section taken along line C-C′ of FIG. 7.

FIG. 9 is a cross-sectional view of a semiconductor device according to some embodiments.

FIGS. 10 to 15 are cross-sectional views showing a manufacturing process of a semiconductor device according to some embodiments.

### DETAILED DESCRIPTION OF THE EMBODIMENTS

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly explain the present disclosure, parts irrelevant to the description are omitted, and the same reference numerals are used for identical or similar components throughout the specification.

In addition, the size and thickness of each component shown in the drawing are arbitrarily shown for convenience of explanation, so the present disclosure is not necessarily limited to what is shown. To clearly represent the various layers and areas in the drawing, the thickness is enlarged and shown. And in the drawing, for convenience of explanation, the thickness of some layers and areas is exaggerated.

Also, when we say that a part, such as a layer, membrane, region, or plate, is “above” or “on” another part, this includes not only cases where it is “directly on” the other part, but also cases where there are other parts in between. Conversely, when we say that a part is “directly on” another part, we mean that there is no other part in between. Also, being “above” or “on” a reference part means being located above or below the reference part, and does not necessarily mean being located “above” or “on” the opposite direction of gravity.

Additionally, throughout the specification, whenever a part is said to “include” a component, this does not mean that it excludes other components, but rather that it may include other components, unless otherwise specifically stated.

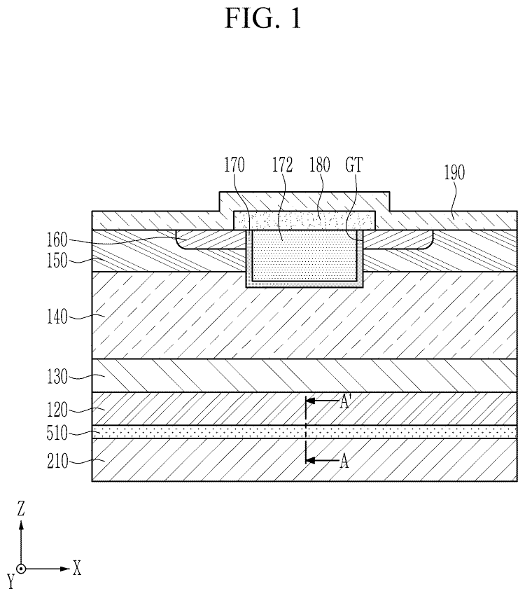

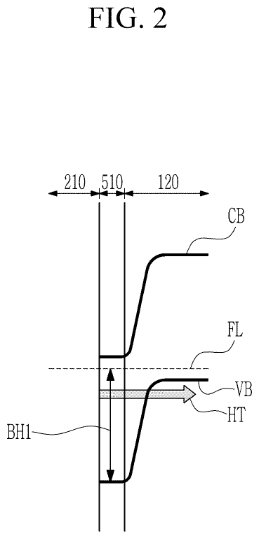

Hereinafter, a semiconductor device according to some embodiments will be described with reference to FIGS. 1 and 2.

FIG. 1 is a cross-sectional view of a semiconductor device according to some embodiments. FIG. 2 is an energy band diagram of a cross-section taken along line A-A′ of FIG. 1.

Referring to FIG. 1, a semiconductor device according to some embodiments may include a collector electrode 210, a first semiconductor layer 120 of a first conductivity type, a second semiconductor layer 140 of a second conductivity type, a first well region 150 of the first conductivity type, and a second well region 160 of the second conductivity type, which are stacked on the collector electrode 210, an emitter electrode 190 positioned on the second well region 160, a gate electrode 172 adjacent to the first well region 150, a gate insulating layer 170 positioned between the gate electrode 172 and the first well region 150, and a tunneling layer 510 positioned between the collector electrode 210 and the first semiconductor layer 120.

In some embodiments, the first semiconductor layer 120, the second semiconductor layer 140, the first well region 150, and the second well region 160 may be stacked on the collector electrode 210. For example, the first semiconductor layer 120 may be positioned on the collector electrode 210. The second semiconductor layer 140 may be positioned on the first semiconductor layer 120. The first well region 150 may be located within the second semiconductor layer 140. A lower surface of the first well region 150 may be covered by the second semiconductor layer 140. A side surface of the first well region 150 may be covered by a gate insulating layer 170. The second well region 160 may be located within the first well region 150. The second well region 160 may be surrounded by the first well region 150. One side surface and a lower surface of the second well region 160 may be covered by the first well region 150. The other side surface of the second well region 160 may be covered by the gate insulating layer 170.

However, the examples are not limited to this. For example, the substrate may be positioned between the first semiconductor layer 120 and the collector electrode 210. For example, the first semiconductor layer 120, the second semiconductor layer 140, the first well region 150, and the second well region 160 may be stacked on a front surface of the substrate. The collector electrode 210 may be located on a back surface of the substrate. At this time, the substrate may be a semiconductor substrate including SiC. For example, the substrate may be made of a 4H SiC substrate. In some cases, the substrate may be made of a 3C SiC substrate, a 6H SiC substrate, etc. The substrate may have the second conductivity type. The substrate may be doped with the second conductivity type. The second conductivity type may be n-type, but is not limited thereto. The resistivity of the substrate may be between about 0.005 Ωcm and about 0.035 Ωcm. The thickness of the substrate may be from about 10 μm to about 700 μm. The material, doping type, doping concentration, resistivity, thickness, etc. of the substrate are not limited thereto and may be changed in various ways. The embodiment illustrated in FIG. 1 may be an example in which the substrate is removed from the final structure of the semiconductor device after it has been used in the manufacturing process.

The collector electrode 210 may include a conductive material. For example, the collector electrode 210 may include a metal, an alloy, a conductive metal nitride, a metal silicide, a doped semiconductor material, a conductive metal oxide, a conductive metal nitride, or a combination thereof. The collector electrode 210 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC—N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but is not limited thereto. The collector electrode 210 may be formed of a single layer or a plurality of layers.

In some embodiments, the first semiconductor layer 120, the second semiconductor layer 140, the first well region 150, and the second well region 160 may include a semiconductor material doped with impurities. In some embodiments, the first semiconductor layer 120, the second semiconductor layer 140, the first well region 150, and the second well region 160 may include the same semiconductor material. For example, the first semiconductor layer 120 and the second semiconductor layer 140 may be formed through an epitaxial growth process using the same semiconductor material as a seed. For example, the first well region 150 and the second well region 160 may be formed by doping the second semiconductor layer 140 with impurities (e.g., ions) through an ion implant process.

In some embodiments, the first semiconductor layer 120, the second semiconductor layer 140, the first well region 150, and the second well region 160 may include a semiconductor material having a larger energy band gap than Si. For example, the first semiconductor layer 120, the second semiconductor layer 140, the first well region 150, and the second well region 160 may include SiC, but are not limited thereto.

In some embodiments, the first semiconductor layer 120 may be of the first conductivity type. The second semiconductor layer 140 may be of the second conductivity type. The first well region 150 may be the first conductivity type. The second well region 160 may be of the second conductivity type. The second conductivity type may be different from the first conductivity type. In some embodiments, the first conductivity type may be p-type and the second conductivity type may be n-type. The first semiconductor layer 120 may include a semiconductor material doped with p-type impurities. The second semiconductor layer 140 may include a semiconductor material doped with n-type impurities. The first well region 150 may include a semiconductor material doped with a p-type impurity. The second well region 160 may include a semiconductor material doped with n-type impurities.

In some embodiments, a doping concentration of the second semiconductor layer 140 may be greater than or equal to about 1*10¹⁴ cm⁻³ and less than or equal to about 1*10¹⁷ cm⁻³. A thickness of the second semiconductor layer 140 may be about 1 μm or more and about 13 μm or less. The doping concentration, thickness, etc. of the second semiconductor layer 140 are not limited thereto and may be changed in various ways.

In some embodiments, a doping concentration of the first well region 150 may be greater than or equal to about 1*10¹⁷ cm⁻³ and less than or equal to about 1*10¹⁹ cm⁻³. A thickness of the first well region 150 may be about 0.3 μm or more and about 1.1 μm or less. The doping concentration, thickness, etc. of the first well region 150 are not limited thereto and may be changed in various ways.

In some embodiments, a doping concentration of the second well region 160 may be higher than the doping concentration of the second semiconductor layer 140. The doping concentration of the second well region 160 may be about 1*10¹⁷ cm⁻³ or more and about 5*10²⁰ cm⁻³ or less. A thickness of the second well region 160 may be about 0.1 μm or more and about 0.5 μm or less. The doping concentration, thickness, etc. of the second well region 160 are not limited thereto and may be changed in various ways.

In some embodiments, a doping concentration of the first semiconductor layer 120 may be higher than the doping concentration of the first well region 150, but is not limited thereto.

In some embodiments, a third semiconductor layer 130 may be positioned between the first semiconductor layer 120 and the second semiconductor layer 140. For example, the third semiconductor layer 130 may be formed through an epitaxial growth process using the same semiconductor material as the first semiconductor layer 120 and the second semiconductor layer 140 as a seed.

In some embodiments, the third semiconductor layer 130 may include a semiconductor material doped with an n-type impurity. In some embodiments, the doping concentration of the third semiconductor layer 130 may be higher than the doping concentration of the second semiconductor layer 140. For example, the third semiconductor layer 130 may be a buffer layer. A semiconductor device according to some embodiments may improve switching speed and reduce on-resistance by including the buffer layer. According to some embodiments, a semiconductor device including the buffer layer may be a punch through IGBT.

However, it is not limited to the illustrated embodiment. For example, the third semiconductor layer 130 may be omitted. For example, the second semiconductor layer 140 may be positioned directly on the first semiconductor layer 120. A semiconductor device according to some embodiments has improved voltage blocking capability and may operate stably even at high temperatures by omitting the buffer layer. According to some embodiments of the present disclosure, a semiconductor device without a buffer layer may be a non-punch through IGBT.

As another example, the third semiconductor layer 130 may be a field stop layer. A semiconductor device according to some embodiments may have the advantages of both the punch through IGBT and the non-punch through IGBT by including the field stop layer. For example, a semiconductor device according to some embodiments may provide low on-resistance and fast switching speed, and high voltage blocking capability and high temperature stability by including the field stop layer. According to some embodiments, a semiconductor device including the field stop layer may be a field stop IGBT.

In some embodiments, the semiconductor device may include a plurality of first well regions 150 spaced apart in a first direction X and a plurality of second well regions 160 spaced apart in the first direction X. The first direction X may be a direction parallel to an upper surface of the second semiconductor layer 140. A gate trench GT may be located between the plurality of first well regions 150 spaced apart in the first direction X and between the plurality of second well regions 160 spaced apart in the first direction X.

A semiconductor device according to some embodiments may include a plurality of gate trenches GT spaced apart from each other in the first direction X. Each of the plurality of gate trenches GT is similar to the gate trench in FIG. 1. Each of the plurality of gate trenches GT may be positioned between the plurality of first well regions 150 spaced apart in the first direction X and between the plurality of second well regions 160 spaced apart in the first direction X. The first well region 150 may be located on both sides of each of the plurality of gate trenches GT. A second well region 160 may be located on both sides of each of the plurality of gate trenches GT.

The gate trench GT may have a depth along a third direction Z. The third direction Z may be a direction perpendicular to the upper surface of the second semiconductor layer 140. The third direction Z may be a direction perpendicular to the first direction X and the second direction Y.

In some embodiments, the lower portion of the gate trench GT may be surrounded by an upper portion of the second semiconductor layer 140. The bottom surface of the gate trench GT may be formed as an upper surface of the second semiconductor layer 140. The sidewall of the gate trench GT may be formed by a side surface of the first well region 150, a side surface of the second well region 160, and a side surface of the second semiconductor layer 140.

In some embodiments, the gate electrode 172 and the gate insulating layer 170 may be positioned within the gate trench GT. The gate insulating layer 170 may cover the sidewalls and bottom surface of the gate trench GT. The gate insulating layer 170 may conformally cover the sidewalls and bottom surface of the gate trench GT.

In some embodiments, the gate electrode 172 may be positioned on the gate insulating layer 170. The gate electrode 172 may be surrounded by the gate insulating layer 170. Both side surfaces and the lower surface of the gate electrode 172 may be covered by the gate insulating layer 170. The gate electrode 172 may be spaced apart from the second semiconductor layer 140, the first well region 150, and the second well region 160 by the gate insulating layer 170. The gate electrode 172 may be insulated from the second semiconductor layer 140, the first well region 150, and the second well region 160 by the gate insulating layer 170.

In some embodiments, the gate electrode 172 may overlap the first well region 150 and the second well region 160 in the first direction X. The gate electrode 172 may overlap the second semiconductor layer 140 in the third direction Z and the first direction X.

In some embodiments, an upper surface of the gate electrode 172 may be positioned at substantially the same level as an upper surface of the first well region 150 and an upper surface of the second well region 160, but is not limited thereto. For example, the upper surface of the gate electrode 172 may be located at a lower level than the upper surface of the first well region 150 and the upper surface of the second well region 160.

The gate electrode 172 may include a conductive material. For example, the gate electrode 172 may include polysilicon doped with impurities, but is not limited thereto. As another example, the gate electrode 172 may include a metal, an alloy, a conductive metal nitride, a metal silicide, a doped semiconductor material, a conductive metal oxide, a conductive metal nitride, or a combination thereof. The gate electrode 172 may be formed of a single layer or a plurality of layers.

The gate insulating layer 170 may include an insulating material. For example, the gate insulating layer 170 may include silicon oxide, but is not limited thereto. As another example, the gate insulating layer 170 may include silicon nitride, silicon oxynitride, silicon carbide, silicon carbonitride, or a combination thereof. The gate insulating layer 170 may be formed of a single layer or a plurality of layers.

A semiconductor device according to some embodiments may further include a protective layer 180 positioned on the gate insulating layer 170 and the gate electrode 172. The protective layer 180 may be further positioned on the second well region 160. The protective layer 180 may cover the upper surface of the gate electrode 172 and an upper surface of the gate insulating layer 170. The protective layer 180 may cover a portion of the upper surface of the second well region 160.

The protective layer 180 may include an insulating material. For example, the protective layer 180 may include silicon oxide, silicon phosphate, silicon nitride, silicon oxynitride, or a combination thereof, but is not limited thereto. The protective layer 180 may be composed of a single layer or a plurality of layers.

In some embodiments, the protective layer 180 may include the same material as the gate insulating layer 170, but is not limited thereto. When the protective layer 180 includes the same material as the gate insulating layer 170, the boundary between the protective layer 180 and the gate insulating layer 170 may not be clearly distinguished at the portion where the protective layer 180 and the gate insulating layer 170 contact.

In some embodiments, the emitter electrode 190 may be positioned on the second well region 160. The emitter electrode 190 may be further positioned on the first well region 150. The emitter electrode 190 may be further positioned on the protective layer 180. The emitter electrode 190 may overlap the gate electrode 172 in the third direction Z. The emitter electrode 190 may be spaced apart from the gate electrode 172 in the third direction Z and the first direction X by the protective layer 180.

In some embodiments, the emitter electrode 190 may be in contact with the second well region 160. The emitter electrode 190 may be in contact with the upper surface of the second well region 160. The emitter electrode 190 is positioned on both sides of the gate electrode 172 and may be in contact with second well regions 160 spaced apart in the first direction X. The emitter electrode 190 may also be in contact with the first well region 150. The emitter electrode 190 may be in contact with the upper surface of the first well region 150. The emitter electrode 190 is positioned on both sides of the gate electrode 172 and may be in contact with first well regions 150 spaced apart in the first direction X.

The emitter electrode 190 may include a conductive material. For example, the emitter electrode 190 may include a metal, an alloy, a conductive metal nitride, a metal silicide, a doped semiconductor material, a conductive metal oxide, a conductive metal oxynitride, or a combination thereof. In some embodiments, the emitter electrode 190 may include the same material as the collector electrode 210, but is not limited thereto. The emitter electrode 190 may be formed of a single layer or a plurality of layers.

A semiconductor device according to some embodiments may be an IGBT. The first semiconductor layer 120, the second semiconductor layer 140, and the first well region 150 may form a BJT of a PNP structure. At this time, the second semiconductor layer 140 may be a base region of the BJT. The second semiconductor layer 140, the gate electrode 172, the gate insulating layer 170, and the second well region 160 may form a MOSFET. The second well region 160 may be a source region of the MOSFET, and the second semiconductor layer 140 adjacent to a lower surface of the gate electrode 172 may be a drain region of the MOSFET. The first well region 150 adjacent to the gate electrode 172 may be a channel region. When a channel is formed in the first well region 150 by a voltage applied to the gate electrode 172, current may flow between the second well region 160 and the second semiconductor layer 140. Accordingly, the BJT may be turned on. For example, current may flow between the emitter electrode 190 and the collector electrode 210. At this time, holes may move from the collector electrode 210 to the emitter electrode 190. Excellent switching characteristics may be secured by MOSFET, and excellent current driving characteristics may be secured by BJT. IGBTs may be used, for example, as power devices, but are not limited thereto, and their applications may vary.

In order for an ohmic contact to be formed between the first semiconductor layer 120 doped with a p-type impurity and including a semiconductor material having a larger energy band gap than Si and the collector electrode 210 including a metal material, a work function of the material of the collector electrode 210 may have to be greater than a work function of the material of the first semiconductor layer 120. However, metallic materials with a larger work function than semiconductor materials with a larger energy band gap than Si are limited, and the activation energy of p-type impurities doped into semiconductor materials with a larger energy band gap than Si may be large. Accordingly, it is difficult to form an ohmic contact between the collector electrode 210 and the first semiconductor layer 120. Even if an ohmic contact is formed between the collector electrode 210 and the first semiconductor layer 120 through high-temperature heat treatment, the ohmic contact may be unstable and the characteristics of the device may deteriorate.

A semiconductor device according to some embodiments may include the tunneling layer 510 positioned between the collector electrode 210 and the first semiconductor layer 120. Accordingly, hole tunneling occurs between the collector electrode 210 and the first semiconductor layer 120, and current may flow. According to some embodiments, the semiconductor device includes the tunneling layer 510, so that an ohmic contact may be formed between the collector electrode 210 and the first semiconductor layer 120.

In some embodiments, the tunneling layer 510 may be a semiconductor layer of the second conductivity type. The tunneling layer 510 may be a semiconductor layer of a different conductivity type from the first semiconductor layer 120 of the first conductivity type. In some embodiments, the first conductivity type may be p-type and the second conductivity type may be n-type. By positioning the tunneling layer 510 of the second conductivity type between the collector electrode 210 and the first conductive semiconductor layer 120, the hole barrier height between the collector electrode 210 and the first conductive semiconductor layer 120 may be increased. Accordingly, a hole tunneling may occur and holes may be injected into the first semiconductor layer 120. Here, a hole barrier height refers to an energy barrier that a hole must overcome. Hole tunneling is a phenomenon in which holes move through the quantum tunneling effect without directly crossing the energy barrier.

In some embodiments, a doping concentration of the tunneling layer 510 may be higher than the doping concentration of the second semiconductor layer 140. The doping concentration of the tunneling layer 510 may be higher than the doping concentration of the second well region 160. In some embodiments, the doping concentration of the tunneling layer 510 may be greater than or equal to about 1*10¹⁹ cm⁻³ and less than or equal to about 5*10²¹ cm⁻³. Preferably, the doping concentration of the tunneling layer 510 may be about 1*10²⁰ cm⁻³ or more and about 1*10²¹ cm⁻³ or less.

The thinner the tunneling layer 510, the more likely the tunneling is to occur. I some embodiments, the tunneling layer 510 may be thinner than the first semiconductor layer 120. The tunneling layer 510 may be thinner than the second semiconductor layer 140. The tunneling layer 510 may be thinner than the third semiconductor layer 130. The tunneling layer 510 may be thinner than the first well region 150. The tunneling layer 510 may be thinner than the second well region 160.

In some embodiments, a thickness of the tunneling layer 510 may be less than or equal to about 20 nm. When the thickness of the tunneling layer 510 is about 20 nm or less, the hole tunneling may occur easily. The occurrence of a tunneling may mean that the number of holes injected into the first semiconductor layer 120 per unit volume increases due to the tunneling effect. When the number of holes per unit volume injected into the first semiconductor layer 120 exceeds a specified value, an ohmic contact may be formed between the collector electrode 210 and the first semiconductor layer 120. In some embodiments, the collector electrode 210 and the first semiconductor layer 120 may be in ohmic contact since the thickness of the tunneling layer 510 is about 20 nm or less.

Referring to FIG. 2, the tunneling layer 510 may be positioned between the collector electrode 210 and the first semiconductor layer 120. In some embodiments, the tunneling layer 510 may be in contact with the first semiconductor layer 120.

In some embodiments, since the conductivity type of the first semiconductor layer 120 is p-type, the Fermi level FL of the first semiconductor layer 120 may be adjacent to the valence band VB among the conduction band CB and the valence band VB. In some embodiments, since the conductivity type of the tunneling layer 510 is n-type, the Fermi level FL of the tunneling layer 510 may be adjacent to the conduction band CB among the conduction band CB and the valence band VB.

As the tunneling layer 510 and the first semiconductor layer 120 are in contact with each other, energy band structures of the tunneling layer 510 and the first semiconductor layer 120 may change so that the Fermi levels FL of both become aligned. In some embodiments, as the tunneling layer 510 and the first semiconductor layer 120 are in contact with each other, the valence band VB of the first semiconductor layer 120 may rise, and the valence band VB of the tunneling layer 510 may fall. Accordingly, the hole barrier height BH1 that holes must overcome to be injected into the first semiconductor layer 120 may be increased. Here, the hole barrier height BH1 may be the height from the valence band VB of the tunneling layer 510 lowered to the Fermi level FL. Due to the increased hole barrier height BH1, holes may be injected into the first semiconductor layer 120 through the quantum tunneling without directly crossing the energy barrier. The arrow HT shown in FIG. 2 indicates the direction of hole tunneling and injection into the first semiconductor layer 120.

At this time, when the tunneling layer 510 is thin, a hole tunneling may occur. The thinner the tunneling layer 510, the more likely the hole tunneling may occur. In some embodiments, the thickness of the tunneling layer 510 may be less than or equal to about 20 nm. When the thickness of the tunneling layer 510 is about 20 nm or less, an ohmic contact may be formed between the collector electrode 210 and the first semiconductor layer 120.

A semiconductor device according to some embodiments may include the tunneling layer 510 of the second conductivity type between the collector electrode 210 and the first semiconductor layer 120 of the first conductivity type. The second conductivity type may be different from the first conductivity type. The tunneling layer 510 may be thinner than the first semiconductor layer 120. Accordingly, even if the first semiconductor layer 120 includes a p-type impurity and includes a semiconductor material having a larger energy band gap than Si, and the work function of the material forming the collector electrode 210 is not larger than the work function of the material forming the first semiconductor layer 120, the collector electrode 210 and the first semiconductor layer 120 of the semiconductor device according to some embodiments may be in ohmic contact.

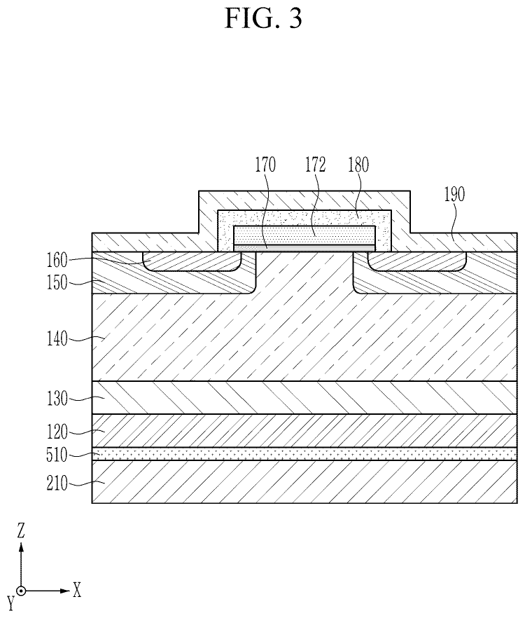

Hereinafter, a modified example of a semiconductor device according to the embodiment of FIG. 1 will be described with reference to FIG. 3.

FIG. 3 is a cross-sectional view of a semiconductor device according to some embodiments. The embodiment illustrated in FIG. 3 may differ from the embodiment illustrated in FIG. 1 only in the structure of the gate insulating layer 170 and the gate electrode 172. In the embodiment illustrated in FIG. 3, the same components as in the embodiment illustrated in FIG. 1 may be referenced by the same drawing reference numerals. For the embodiment illustrated in FIG. 3, the differences from the embodiment illustrated in FIG. 1 will be mainly explained, and any overlapping explanations will be brief or omitted.

Referring to FIG. 3, the gate insulating layer 170 and the gate electrode 172 of a semiconductor device according to some embodiments may be positioned on the upper surface of the second semiconductor layer 140, the upper surface of the first well region 150, and the upper surface of the second well region 160. The gate insulating layer 170 may cover a portion of the upper surface of the first well region 150 and a portion of the upper surface of the second well region 160. The gate insulating layer 170 may cover an upper surface of a portion of the second semiconductor layer 140, and the portion of the second semiconductor layer 140 is located between the first well regions 150 spaced apart in the first direction X. The lower surface of the gate electrode 172 may be covered by the gate insulating layer 170. The gate electrode 172 may be spaced apart and insulated from the upper surface of the second semiconductor layer 140, the upper surface of the first well region 150, and the upper surface of the second well region 160 by the gate insulating layer 170.

In some embodiments, the gate electrode 172 may overlap the second semiconductor layer 140, the first well region 150, and the second well region 160 in the third direction Z. Unlike the embodiment illustrated in FIG. 1, the gate electrode 172 may not overlap the second semiconductor layer 140, the first well region 150, and the second well region 160 in the first direction X.

In some embodiments, the lower surface of the gate electrode 172 may be located at a higher level than the upper surface of the first well region 150 and the upper surface of the second well region 160.

In the embodiment illustrated in FIG. 1, the gate insulating layer 170 and the gate electrode 172 may be embedded on an upper portion of the second semiconductor layer 140. On the other hand, in the embodiment illustrated in FIG. 3, the gate insulating layer 170 and the gate electrode 172 may be positioned on the second semiconductor layer 140.

In the embodiment illustrated in FIG. 1, the protective layer 180 may cover the upper surface of the gate insulating layer 170 and the gate electrode 172. In the embodiment illustrated in FIG. 3, the protective layer 180 may further cover the side surfaces of the gate insulating layer 170 and the gate electrode 172.

A semiconductor device according to some embodiments may include the tunneling layer 510 of the second conductivity type between the collector electrode 210 and the first semiconductor layer 120 of the first conductivity type. The second conductivity type may be different from the first conductivity type. The tunneling layer 510 may be thinner than the first semiconductor layer 120. The thinner the tunneling layer 510, the more likely the tunneling may occur. For the tunneling layer 510, the description of the embodiment illustrated in FIG. 1 may be applied identically or similarly.

In some embodiments, the thickness of the tunneling layer 510 may be less than or equal to about 20 nm. When the thickness of the tunneling layer 510 is about 20 nm or less, the hole tunneling may occur easily. In some embodiments, the collector electrode 210 and the first semiconductor layer 120 may be in ohmic contact as the thickness of the tunneling layer 510 is about 20 nm or less.

According to some embodiments, even if the first semiconductor layer 120 includes a p-type impurity and includes a semiconductor material having a larger energy band gap than Si, and the work function of the material forming the collector electrode 210 is not larger than the work function of the material forming the first semiconductor layer 120, the collector electrode 210 and the first semiconductor layer 120 of a semiconductor device according to some embodiments may be in ohmic contact.

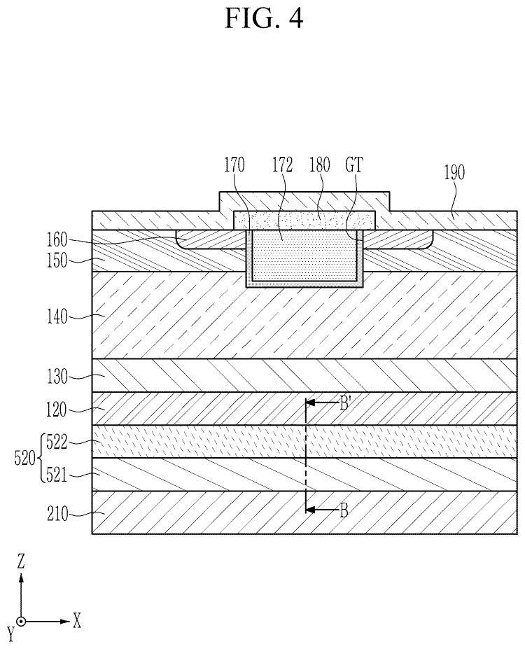

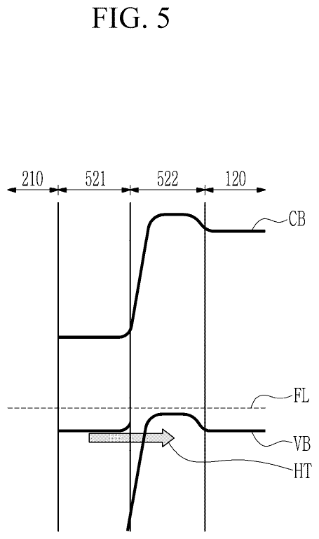

Hereinafter, a modified example of the semiconductor device according to the embodiment of FIG. 1 will be described with reference to FIGS. 4 and 5.

FIG. 4 is a cross-sectional view of a semiconductor device according to some embodiments. FIG. 5 is an energy band diagram of a cross-section taken along line B-B′ of FIG. 4. The embodiment illustrated in FIG. 4 differs from the embodiment illustrated in FIG. 1 in that the tunneling layer 520 is composed of two layers including materials having different energy band gaps, but the remaining components may be the same. In the embodiment illustrated in FIG. 4, the same components as in the embodiment illustrated in FIG. 1 may be referenced with the same drawing reference numerals. For the embodiment illustrated in FIG. 4, the differences from the embodiment illustrated in FIG. 1 will be mainly explained, and any overlapping explanations will be brief or omitted.

Referring to FIG. 4, a semiconductor device according to some embodiments may include a tunneling layer 520 between the collector electrode 210 and the first semiconductor layer 120 of the first conductivity type. The tunneling layer 520 may include a first tunneling layer 521 positioned on the first semiconductor layer 120 and a second tunneling layer 522 positioned on the first tunneling layer 521. The first semiconductor layer 120 may be positioned on the second tunneling layer 522.

In some embodiments, the first tunneling layer 521 and the second tunneling layer 522 may be semiconductor layers of the first conductivity type. The first tunneling layer 521 and the second tunneling layer 522 may be semiconductor layers of the same conductivity type as the first semiconductor layer 120. In some embodiments, the first conductivity type may be p-type. The first tunneling layer 521 and the second tunneling layer 522 may include a semiconductor material doped with p-type impurities.

In some embodiments, the first semiconductor layer 120, the second semiconductor layer 140, the first well region 150, and the second well region 160 may include a semiconductor material having a larger energy band gap than Si. For example, the first semiconductor layer 120, the second semiconductor layer 140, the first well region 150, and the second well region 160 may include SiC.

In some embodiments, the first tunneling layer 521 may include a semiconductor material having a smaller energy band gap than the first semiconductor layer 120. The first tunneling layer 521 may include a semiconductor material that contains the same elements as the first semiconductor layer 120, but has a smaller energy band gap than the material of the first semiconductor layer 120.

In some embodiments, the first semiconductor layer 120 and the first tunneling layer 521 may include Si and C, and the first tunneling layer 521 may further include elements other than Si and C. For example, the first tunneling layer 521 may further include Ge in addition to Si and C. For example, the first semiconductor layer 120 may include SiC, and the first tunneling layer 521 may include SiₓGe_{y}C_{1-x-y}. In some embodiments, the content of elements in the first tunneling layer 521, other than those that are the same as elements of the first semiconductor layer 120, may be 50 at% or less. For example, the first tunneling layer 521 may include SiₓGe_{y}C_{1-x-y}, where 0<y≤0.5. Preferably, in the first tunneling layer 521, the content of an element different from those in the first semiconductor layer 120 is 50 at % or less, and may be equal to or greater than the content (an atomic concentration (at %)) of Si. For example, the first tunneling layer 521 may include SiₓGe_{y}C_{1-x-y}, where 0<y≤0.5 and x≤y. In some embodiments, the atomic ratio of elements in the first tunneling layer 521 that are the same as those in the first semiconductor layer 120 may be 1:1, but is not limited thereto. For example, the first tunneling layer 521 may include SiₓGe_{y}C_{1-x-y}, and x:1−x−y may be 1:1, but is not limited thereto.

However, Ge is only an example, and the first tunneling layer 521 may contain the same elements as the first semiconductor layer 120 but may also contain other elements so that the energy band gap is smaller than that of the first semiconductor layer 120.

The above-described embodiment is a case where the first tunneling layer 521 includes the same element as the first semiconductor layer 120 and further includes a different element, but the embodiment is not limited thereto. For example, the first semiconductor layer 120 and the first tunneling layer 521 may include Si and C, and the Si content (at %) of the first tunneling layer 521 may be higher than the Si content (at %) of the first semiconductor layer 120. For example, the first semiconductor layer 120 may include SiₘC₁₋ₘ, the first tunneling layer 521 may include SiₙC₁₋ₙ, and n>m.

In some embodiments, a doping concentration of the first tunneling layer 521 including Si and C may be about 1*10¹⁸ cm⁻³ or more and about 1*10²⁰ cm⁻³ or less.

In some embodiments, the second tunneling layer 522 may include a semiconductor material having a larger energy band gap than the first tunneling layer 521. The second tunneling layer 522 may include the same elements as the first semiconductor layer 120 and may include a semiconductor material having a larger energy band gap than the material of the first tunneling layer 521. In some embodiments, the second tunneling layer 522 may include the same material as the first semiconductor layer 120. For example, the first tunneling layer 521 may include SiₓGe_{y}C_{1-x-y}, and the second tunneling layer 522 and the first semiconductor layer 120 may include SiC.

In some embodiments, a doping concentration of the second tunneling layer 522 may be higher than the doping concentration of the first tunneling layer 521. The doping concentration of the second tunneling layer 522 may be higher than the doping concentration of the first semiconductor layer 120. In some embodiments, the doping concentration of the second tunneling layer 522 including Si and C may be greater than or equal to about 1*10¹⁹ cm⁻³ and less than or equal to about 5*10²¹ cm⁻³. Preferably, the doping concentration of the second tunneling layer 522 may be about 1*10²⁰ cm⁻³ or more and about 1*10²¹ cm⁻³ or less.

The above-described embodiments include a case where the first semiconductor layer 120, the second semiconductor layer 140, the first well region 150, and the second well region 160 include SiC, but the embodiments are not limited thereto. For example, the first semiconductor layer 120, the second semiconductor layer 140, the first well region 150, and the second well region 160 may include GaN.

In some embodiments, the first tunneling layer 521 may include a semiconductor material having a smaller energy band gap than the first semiconductor layer 120. The first tunneling layer 521 may include a semiconductor material that contains the same elements as the first semiconductor layer 120, but has a smaller energy band gap than the material of the first semiconductor layer 120.

In some embodiments, the first semiconductor layer 120 and the first tunneling layer 521 may include Ga and N, and the first tunneling layer 521 may further include elements other than Ga and N. For example, the first tunneling layer 521 may further include In in addition to Ga and N. For example, the first semiconductor layer 120 may include GaN, and the first tunneling layer 521 may include InₚGa₁₋ₚN. In some embodiments, the content of elements added other than the same elements as those in the first semiconductor layer 120 among the elements of the first tunneling layer 521 may be 50 at % or less. For example, the first tunneling layer 521 may include InₚGa₁₋ₚN, and 0<p≤0.5. Preferably, the content of an element added other than the same element as the first semiconductor layer 120 among the elements of the first tunneling layer 521 is 50 at % or less, and may be equal to or less than the content (at %) of Ga. For example, the first tunneling layer 521 may include InₚGa₁₋ₚN, and 0<p≤0.5. In some embodiments, the atomic ratio of the same elements as those in the first semiconductor layer 120 among the elements of the first tunneling layer 521 may be 1:1, but is not limited thereto.

However, In is only an example, and the first tunneling layer 521 may contain the same elements as the first semiconductor layer 120 but may also contain other elements so that the energy band gap is smaller than that of the first semiconductor layer 120.

In some embodiments, the doping concentration of the first tunneling layer 521 including Ga and N may be about 1*10¹⁷ cm⁻³ or more and about 1*10²⁰ cm⁻³ or less.

In some embodiments, the second tunneling layer 522 may include a semiconductor material having a larger energy band gap than the first tunneling layer 521. The second tunneling layer 522 may include the same elements as the first semiconductor layer 120 and may include a semiconductor material having a larger energy band gap than the material of the first tunneling layer 521. In some embodiments, the second tunneling layer 522 may include the same material as the first semiconductor layer 120. For example, the first tunneling layer 521 may include InₚGa₁₋ₚN, and the second tunneling layer 522 and the first semiconductor layer 120 may include GaN.

In some embodiments, the doping concentration of the second tunneling layer 522 may be higher than the doping concentration of the first tunneling layer 521. The doping concentration of the second tunneling layer 522 may be higher than the doping concentration of the first semiconductor layer 120. In some embodiments, the doping concentration of the second tunneling layer 522 including Ga and N may be greater than or equal to about 1*10¹⁸ cm⁻³ and less than or equal to about 1*10²⁰ cm⁻³.

Referring to FIG. 5, the tunneling layer 520 may be positioned between the collector electrode 210 and the first semiconductor layer 120. The tunneling layer 520 may include the first tunneling layer 521 and the second tunneling layer 522. The first tunneling layer 521 may be positioned between the collector electrode 210 and the first semiconductor layer 120, and the second tunneling layer 522 may be positioned between the first tunneling layer 521 and the first semiconductor layer 120. Among the first tunneling layer 521 and the second tunneling layer 522, the first tunneling layer 521 may be closer to the collector electrode 210. Among the first tunneling layer 521 and the second tunneling layer 522, the second tunneling layer 522 may be closer to the first semiconductor layer 120. In some embodiments, the first tunneling layer 521 may be in contact with the second tunneling layer 522. In some embodiments, the second tunneling layer 522 may be in contact with the first semiconductor layer 120.

In some embodiments, as the conductivity types of the first semiconductor layer 120, the first tunneling layer 521, and the second tunneling layer 522 are p-type, the Fermi level FL of each of the first semiconductor layer 120, the first tunneling layer 521, and the second tunneling layer 522 may be adjacent to the valence band VB among the conduction band CB and the valence band VB.

In some embodiments, the energy band gap of the first tunneling layer 521 may be smaller than the energy band gap of the second tunneling layer 522. The energy band gap refers to the energy difference between the conduction band CB and the valence band VB, which may correspond to the height difference between the conduction band CB level and the valence band VB level. As the first tunneling layer 521 and the second tunneling layer 522 are in contact with each other, energy band structures of the first tunneling layer 521 and the second tunneling layer 522 may change so that the Fermi levels FL of both become aligned. In some embodiments, as the first tunneling layer 521 and the second tunneling layer 522 are in contact with each other, a notch may be formed between the first tunneling layer 521 and the second tunneling layer 522 in which the valence band VB is sharply and discontinuously bent. Holes may accumulate in the notch formed in the valence band VB. As the hole density increases, the tunneling probability of the holes may increase. In some embodiments, the notch is formed in the valence band VB at a contact surface of the first tunneling layer 521 including a material having a relatively small energy band gap and the second tunneling layer 522 including a material having a relatively large energy band gap, and holes accumulated in the notch may be injected into the second tunneling layer 522 through a quantum tunneling. The arrow HT shown in FIG. 5 indicates the direction of hole tunneling and injection into the second tunneling layer 522.

In some embodiments, the doping concentration of the second tunneling layer 522 may be higher than the doping concentration of the first tunneling layer 521. In some embodiments, the first tunneling layer 521 and the second tunneling layer 522 may include a semiconductor material doped with a p-type impurity. In this case, as the doping concentration of the second tunneling layer 522 is higher than the doping concentration of the first tunneling layer 521, the valence band VB of the second tunneling layer 522 may be closer to the Fermi level FL than the valence band of the first tunneling layer 521. In this case, a depth of the notch formed between the first tunneling layer 521 and the second tunneling layer 522 may be deeper. As the notch deepens, the density of holes accumulated in the notch increases, and the hole tunneling may occur more easily.

In some embodiments, the material of the second tunneling layer 522 and the material of the first semiconductor layer 120 may have the same energy band gap. The second tunneling layer 522 may include the same semiconductor material as the first semiconductor layer 120.

In some embodiments, the second tunneling layer 522 includes the same semiconductor material as the first semiconductor layer 120, but the doping concentration of the second tunneling layer 522 may be higher than the doping concentration of the first semiconductor layer 120. In some embodiments, the second tunneling layer 522 and the first semiconductor layer 120 may include a semiconductor material doped with a p-type impurity. In this case, since the doping concentration of the second tunneling layer 522 is higher than the doping concentration of the first semiconductor layer 120, the valence band VB of the second tunneling layer 522 may be closer to the Fermi level FL than the valence band of the first semiconductor layer 120. For example, the valence band VB of the second tunneling layer 522 may have a higher energy level than the valence band of the first semiconductor layer 120. Accordingly, holes may move from the second tunneling layer 522 to the first semiconductor layer 120.

A semiconductor device according to some embodiments includes the first tunneling layer 521 of the first conductivity type positioned between the collector electrode 210 and the first semiconductor layer 120 of the first conductivity type, and the first tunneling layer 521 may include a semiconductor material having a smaller energy band gap than the first semiconductor layer 120. Since the first tunneling layer 521 has a smaller energy band gap than the first semiconductor layer 120, a work function of the first tunneling layer 521 is smaller than the work function of the first semiconductor layer 120, and an activation energy of the p-type impurity in the first tunneling layer 521 may be smaller than an activation energy of the first semiconductor layer 120. Accordingly, when the first tunneling layer 521 is positioned between the collector electrode 210 and the first semiconductor layer 120 rather than when the collector electrode 210 is directly connected to the first semiconductor layer 120, it is easier for the collector electrode 210 and the first semiconductor layer 120 to make ohmic contact.

A semiconductor device according to some embodiments includes the second tunneling layer 522 of the first conductivity type between the first tunneling layer 521 and the first semiconductor layer 120, and the second tunneling layer 522 may include a semiconductor material having a larger energy band gap than the first tunneling layer 521. In some embodiments, the doping concentration of the second tunneling layer 522 may be higher than the doping concentration of the first tunneling layer 521. As the first tunneling layer 521 and the second tunneling layer 522 are in contact with each other, a valence band VB notch may be formed at the contact surface of the first tunneling layer 521 and the second tunneling layer 522, and as holes accumulate in the notch and the hole density increases, hole tunneling may occur easily. The hole may move from the first tunneling layer 521 to the second tunneling layer 522 through the hole tunneling, and may move from the second tunneling layer 522 to the first semiconductor layer 120 due to the energy level difference of the valence band VB according to the doping concentration. Accordingly, even if the first semiconductor layer 120 includes a p-type impurity and a semiconductor material having a larger energy band gap than Si, and the work function of the material forming the collector electrode 210 is not larger than the work function of the material forming the first semiconductor layer 120, the collector electrode 210 and the first semiconductor layer 120 of the semiconductor device according to some embodiments may be in ohmic contact.

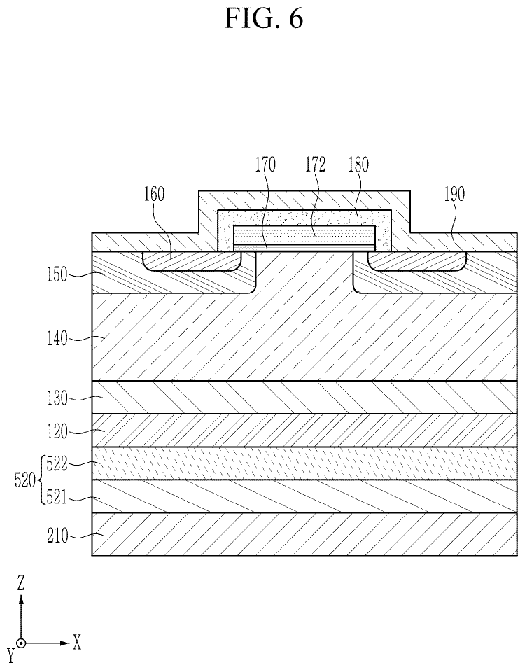

Hereinafter, a modified example of the semiconductor device according to the embodiment of FIG. 4 will be described with reference to FIG. 6.

FIG. 6 is a cross-sectional view of a semiconductor device according to some embodiments. The embodiment illustrated in FIG. 6 may differ from the embodiment illustrated in FIG. 4 only in the structure of the gate insulating layer 170 and the gate electrode 172. In the embodiment illustrated in FIG. 6, the same components as in the embodiment illustrated in FIG. 4 may be referenced by the same drawing reference numerals. For the embodiment illustrated in FIG. 6, the differences from the embodiment illustrated in FIG. 4 will be mainly explained, and any overlapping explanations will be brief or omitted. The embodiment illustrated in FIG. 6 may be a modified version of the embodiment illustrated in FIG. 4, in which only the structures of the gate insulating layer 170 and the gate electrode 172 are modified to be the same as those illustrated in FIG. 3. The structure of the gate insulating layer 170 and the gate electrode 172 in the embodiment illustrated in FIG. 6 may be applied identically or similarly to the description referring to FIG. 3.

Referring to FIG. 6, the gate insulating layer 170 and the gate electrode 172 of a semiconductor device according to some embodiments may be positioned on the upper surface of the second semiconductor layer 140, the upper surface of the first well region 150, and the upper surface of the second well region 160. The gate insulating layer 170 may cover a portion of the upper surface of the first well region 150 and a portion of the upper surface of the second well region 160. The gate insulating layer 170 may cover the upper surface of the second semiconductor layer 140 located between the first well regions 150 spaced apart in the first direction X. The lower surface of the gate electrode 172 may be covered by the gate insulating layer 170. The gate electrode 172 may be spaced apart and insulated from the upper surface of the second semiconductor layer 140, the upper surface of the first well region 150, and the upper surface of the second well region 160 by the gate insulating layer 170.

In some embodiments, the gate electrode 172 may overlap the second semiconductor layer 140, the first well region 150, and the second well region 160 in the third direction Z. Unlike the embodiment illustrated in FIG. 4, the gate electrode 172 may not overlap the second semiconductor layer 140, the first well region 150, and the second well region 160 in the first direction X.

In some embodiments, the lower surface of the gate electrode 172 may be located at a higher level than the upper surface of the first well region 150 and the upper surface of the second well region 160.

In the embodiment illustrated in FIG. 4, the gate insulating layer 170 and the gate electrode 172 may be embedded in an upper portion of the second semiconductor layer 140. On the other hand, in the embodiment illustrated in FIG. 6, the gate insulating layer 170 and the gate electrode 172 may be positioned above the second semiconductor layer 140.

In the embodiment illustrated in FIG. 4, the protective layer 180 may cover the upper surface of the gate insulating layer 170 and the gate electrode 172. In the embodiment illustrated in FIG. 6, the protective layer 180 may further cover the side surfaces of the gate insulating layer 170 and the gate electrode 172.

A semiconductor device according to some embodiments may include the first tunneling layer 521 and the second tunneling layer 522 of the first conductivity type between the collector electrode 210 and the first semiconductor layer 120 of the first conductivity type. The first tunneling layer 521 may include a material having a smaller energy band gap than the first semiconductor layer 120, and the second tunneling layer 522 may include a material having a larger energy band gap than the first tunneling layer 521. Accordingly, a valence band notch may be formed at the contact surface of the first tunneling layer 521 and the second tunneling layer 522, and holes accumulated in the notch may tunnel and be injected into the second tunneling layer 522.

In some embodiments, the doping concentration of the second tunneling layer 522 may be higher than the doping concentration of the first tunneling layer 521. Accordingly, the depth of the valence band notch at the contact surface of the first tunneling layer 521 and the second tunneling layer 522 may be deepened, and more holes may be accumulated in the deep notch, so that the hole tunneling may occur more easily.

In some embodiments, the doping concentration of the second tunneling layer 522 may be higher than the doping concentration of the first semiconductor layer 120. Accordingly, the hole may easily move from the second tunneling layer 522 to the first semiconductor layer 120.

In some embodiments, as the energy band gap of the first tunneling layer 521 is smaller than that of the first semiconductor layer 120, the work function of the first tunneling layer 521 may be smaller than that of the first semiconductor layer 120, and the activation energy of the p-type impurity in the first tunneling layer 521 may be smaller than that of the first semiconductor layer 120. Accordingly, positioning the first tunneling layer 521 between the collector electrode 210 and the first semiconductor layer 120 facilitates ohmic contact between the collector electrode 210 and the first semiconductor layer 120, as compared to directly connecting the collector electrode 210 to the first semiconductor layer 120.

In some embodiments, the first tunneling layer 521 including a material having a smaller energy band gap than the first semiconductor layer 120 is positioned on the collector electrode 210, the second tunneling layer 522 including a material having a larger energy band gap than the first tunneling layer 521 and having a higher doping concentration than each of the first tunneling layer 521 and the first semiconductor layer 120 is positioned on the first tunneling layer 521, and the first semiconductor layer 120 is positioned on the second tunneling layer 522, whereby the collector electrode 210 and the first semiconductor layer 120 may be in ohmic contact.

According to some embodiments, even if the first semiconductor layer 120 includes a p-type impurity and includes a semiconductor material having a larger energy band gap than Si, and the work function of the material forming the collector electrode 210 is not larger than the work function of the material forming the first semiconductor layer 120, the collector electrode 210 and the first semiconductor layer 120 of a semiconductor device according to some embodiments may be in ohmic contact.

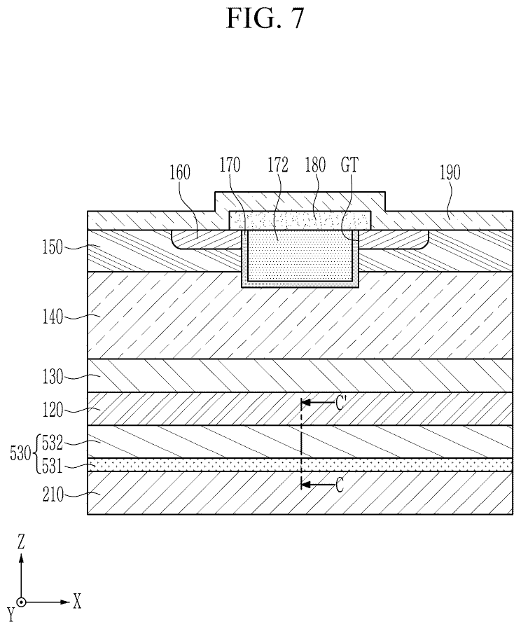

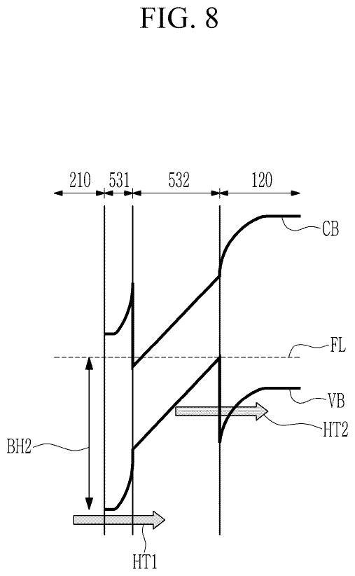

Hereinafter, a modified example of the semiconductor device according to the embodiment of FIG. 1 will be described with reference to FIGS. 7 and 8.

FIG. 7 is a cross-sectional view of a semiconductor device according to some embodiments. FIG. 8 is an energy band diagram of a cross-section taken along line C-C′ of FIG. 7. The embodiment illustrated in FIG. 7 differs from the embodiment illustrated in FIG. 1 in that the tunneling layer 530 has different conductive types and is composed of two layers including materials having different energy band gaps, but the remaining components may be the same. In the embodiment illustrated in FIG. 7, the same components as in the embodiment illustrated in FIG. 1 may be referenced with the same drawing reference numerals. For the embodiment illustrated in FIG. 7, the differences from the embodiment illustrated in FIG. 1 will be mainly explained, and any overlapping explanations will be brief or omitted.

Referring to FIG. 7, a semiconductor device according to some embodiments may include a tunneling layer 530 between the collector electrode 210 and the first semiconductor layer 120 of the first conductivity type. The tunneling layer 530 may include a first tunneling layer 531 positioned on the first semiconductor layer 120 and a second tunneling layer 532 positioned on the first tunneling layer 531. A first semiconductor layer 120 may be positioned on the second tunneling layer 532.

In some embodiments, the first tunneling layer 531 and the second tunneling layer 532 may have different conductivity types. In some embodiments, the first tunneling layer 531 may be a semiconductor layer of the second conductivity type different from that of the first semiconductor layer 120, and the second tunneling layer 532 may be a semiconductor layer of the same first conductivity type as that of the first semiconductor layer 120. In some embodiments, the first conductivity type may be p-type. The first tunneling layer 521 may include a semiconductor material doped with n-type impurities. The second tunneling layer 522 may include a semiconductor material doped with p-type impurities.

In some embodiments, the first tunneling layer 531 of the second conductive type is positioned between the collector electrode 210 and the second tunneling layer 532 of the first conductive type, so that the hole barrier height between the collector electrode 210 and the second tunneling layer 532 may be increased. Accordingly, hole tunneling may occur and holes may be injected into the second tunneling layer 532.

In some embodiments, a doping concentration of the first tunneling layer 531 may be higher than a doping concentration of the second semiconductor layer 140. The doping concentration of the first tunneling layer 531 may be higher than the doping concentration of the second well region 160. In some embodiments, the doping concentration of the first tunneling layer 531 may be greater than or equal to about 1*10¹⁹ cm⁻³ and less than or equal to about 5*10²¹ cm⁻³. Preferably, the doping concentration of the first tunneling layer 531 may be about 1*10²⁰ cm⁻³ or more and about 1*10²¹ cm⁻³ or less.

The thinner the first tunneling layer 531, the more likely the tunneling may occur. In some embodiments, the first tunneling layer 531 may be thinner than the first semiconductor layer 120. The first tunneling layer 531 may be thinner than the second semiconductor layer 140. The first tunneling layer 531 may be thinner than the third semiconductor layer 130. The first tunneling layer 531 may be thinner than the first well region 150. The first tunneling layer 531 may be thinner than the second well region 160. In some embodiments, a thickness of the first tunneling layer 531 may be about 20 nm or less.

In some embodiments, the first semiconductor layer 120, the second semiconductor layer 140, the first well region 150, and the second well region 160 may include a semiconductor material having a larger energy band gap than Si. For example, the first semiconductor layer 120, the second semiconductor layer 140, the first well region 150, and the second well region 160 may include SiC.

In some embodiments, the second tunneling layer 532 may include a semiconductor material having a smaller energy band gap than the first semiconductor layer 120. The second tunneling layer 532 may include a semiconductor material that contains the same elements as the first semiconductor layer 120, but has a smaller energy band gap than the material of the first semiconductor layer 120.

In some embodiments, the first semiconductor layer 120 and the second tunneling layer 532 may include Si and C, and the second tunneling layer 532 may further include elements other than Si and C. For example, the second tunneling layer 532 may further include Ge in addition to Si and C. For example, the first semiconductor layer 120 may include SiC, and the second tunneling layer 532 may include SiₓGe_{y}C_{1-x-y}. In some embodiments, the content of elements added other than the same elements as those in the first semiconductor layer 120 among the elements of the second tunneling layer 532 may be 50 at % or less. For example, the second tunneling layer 532 may include SiₓGe_{y}C_{1-x-y}, where 0<y≤0.5. Preferably, the content of elements added other than the same elements as those in the first semiconductor layer 120 among the elements of the second tunneling layer 532 is 50 at % or less, and may be equal to or greater than the content (at %) of Si. For example, the second tunneling layer 532 may include SiₓGe_{y}C_{1-x-y}, where 0<y≤0.5 and x≤y. In some embodiments, the atomic ratio of the same elements as those in the first semiconductor layer 120 among the elements of the second tunneling layer 532 may be 1:1, but is not limited thereto. For example, the second tunneling layer 532 may include SiₓGe_{y}C_{1-x-y}, and x:1−x−y may be 1:1, but is not limited thereto.

However, Ge is only an example, and the second tunneling layer 532 may contain the same elements as the first semiconductor layer 120 but may also contain other elements so that the energy band gap is smaller than that of the first semiconductor layer 120.

The above-described embodiment is a case where the second tunneling layer 532 includes the same element as the first semiconductor layer 120 and further includes a different element, but the embodiment is not limited thereto. For example, the first semiconductor layer 120 and the second tunneling layer 532 may include Si and C, and the Si content (at %) of the second tunneling layer 532 may be higher than the Si content (at %) of the first semiconductor layer 120. For example, the first semiconductor layer 120 may include SiₘC₁₋ₘ, the second tunneling layer 532 may include SiₙC₁₋ₙ, and n>m.

In some embodiments, a doping concentration of the second tunneling layer 532 including Si and C may be greater than or equal to about 1*10¹⁸ cm⁻³ and less than or equal to about 1*10²⁰ cm⁻³.

In some embodiments, the first tunneling layer 531 may include a semiconductor material having a larger energy band gap than the second tunneling layer 532. An energy band gap of the second tunneling layer 532 may be smaller than an energy band gap of the first tunneling layer 531. The first tunneling layer 531 may include the same elements as the first semiconductor layer 120 and may include a semiconductor material having a larger energy band gap than the material of the second tunneling layer 532. In some embodiments, the first tunneling layer 531 may include the same material as the first semiconductor layer 120. For example, the second tunneling layer 532 may include SiₓGe_{y}C_{1-x-y}, and the first tunneling layer 531 and the first semiconductor layer 120 may include SiC.

The above-described embodiments include a case where the first semiconductor layer 120, the second semiconductor layer 140, the first well region 150, and the second well region 160 include SiC, but the embodiments are not limited thereto. For example, the first semiconductor layer 120, the second semiconductor layer 140, the first well region 150, and the second well region 160 may include GaN.

In some embodiments, the second tunneling layer 532 may include a semiconductor material having a smaller energy band gap than the first semiconductor layer 120. The second tunneling layer 532 may include a semiconductor material that contains the same elements as the first semiconductor layer 120, but has a smaller energy band gap than the material of the first semiconductor layer 120.

In some embodiments, the first semiconductor layer 120 and the second tunneling layer 532 may include Ga and N, and the second tunneling layer 532 may further include elements other than Ga and N. For example, the second tunneling layer 532 may further include In in addition to Ga and N. For example, the first semiconductor layer 120 may include GaN, and the second tunneling layer 532 may include InₚGa₁₋ₚN. In some embodiments, the content of elements added other than the same elements as those in the first semiconductor layer 120 among the elements of the second tunneling layer 532 may be 50 at % or less. For example, the second tunneling layer 532 may include InₚGa₁₋ₚN, and 0<p≤0.5. Preferably, the content of an element added other than the same element as the first semiconductor layer 120 among the elements of the second tunneling layer 532 is 50 at % or less, and may be equal to or less than the content (at %) of Ga. For example, the second tunneling layer 532 may include InₚGa₁₋ₚN, and 0<p≤0.5. In some embodiments, the atomic ratio of the same elements as those in the first semiconductor layer 120 among the elements of the second tunneling layer 532 may be 1:1, but is not limited thereto.

However, In is only an example, and the second tunneling layer 532 may contain the same elements as the first semiconductor layer 120 but may also contain other elements so that the energy band gap is smaller than that of the first semiconductor layer 120.

In some embodiments, the doping concentration of the second tunneling layer 532 including Ga and N may be greater than or equal to about 1*10¹⁸ cm⁻³ and less than or equal to about 1*10²⁰ cm⁻³.

In some embodiments, the first tunneling layer 531 may include a semiconductor material having a larger energy band gap than the second tunneling layer 532. The energy band gap of the second tunneling layer 532 may be smaller than the energy band gap of the first tunneling layer 531. The first tunneling layer 531 may include the same elements as the first semiconductor layer 120 and may include a semiconductor material having a larger energy band gap than the material of the second tunneling layer 532. In some embodiments, the first tunneling layer 531 may include the same material as the first semiconductor layer 120. For example, the second tunneling layer 532 may include InₚGa₁₋ₚN, and the first tunneling layer 531 and the first semiconductor layer 120 may include GaN.

Referring to FIG. 8, the tunneling layer 530 may be positioned between the collector electrode 210 and the first semiconductor layer 120. The tunneling layer 530 may include the first tunneling layer 531 and the second tunneling layer 532. The first tunneling layer 531 may be positioned between the collector electrode 210 and the first semiconductor layer 120, and the second tunneling layer 532 may be positioned between the first tunneling layer 531 and the first semiconductor layer 120. Among the first tunneling layer 531 and the second tunneling layer 532, the first tunneling layer 531 may be closer to the collector electrode 210. Among the first tunneling layer 531 and the second tunneling layer 532, the second tunneling layer 532 may be closer to the first semiconductor layer 120. In some embodiments, the first tunneling layer 531 may be in contact with the second tunneling layer 532. In some embodiments, the second tunneling layer 532 may be in contact with the first semiconductor layer 120.

In some embodiments, as the conductivity types of the second tunneling layer 532 and the first semiconductor layer 120 are p-type, the Fermi level FL of the second tunneling layer 532 and the first semiconductor layer 120 may be adjacent to the valence band VB among the conduction band CB and the valence band VB. In some embodiments, as the conductivity type of the first tunneling layer 531 is n-type, the Fermi level FL of the first tunneling layer 531 may be adjacent to the conduction band CB among the conduction band CB and the valence band VB.

As the first tunneling layer 531 and the second tunneling layer 532 are in contact with each other, energy band structures of the first tunneling layer 531 and the second tunneling layer 532 may change so that the Fermi levels FL of both become aligned. In some embodiments, as the first tunneling layer 531 and the second tunneling layer 532 are in contact with each other, the valence band VB of the second tunneling layer 532 may rise, and the valence band VB of the first tunneling layer 531 may fall. Accordingly, the hole barrier height BH2 that holes must overcome to be injected into the second tunneling layer 532 may be increased. Here, the hole barrier height BH2 may be the height from the valence band VB of the lowered first tunneling layer 531 to the Fermi level FL. Due to the increased hole barrier height BH2, holes may be injected into the second tunneling layer 532 through the quantum tunneling without directly crossing the energy barrier. The first arrow HT1 shown in FIG. 8 indicates the direction of hole tunneling and injection into the second tunneling layer 532.

In some embodiments, the energy band gap of the second tunneling layer 532 may be smaller than the energy band gap of the first tunneling layer 531. At the contact surface between the first tunneling layer 531 and the second tunneling layer 532, the energy level of the valence band VB of the first tunneling layer 531 which has a relatively large energy band gap and is n-type may be lower, and the energy level of the valence band VB of the second tunneling layer 532 which has a relatively small energy band gap and is p-type may be higher. Accordingly, the hole barrier height BH2 that holes must overcome to be injected into the second tunneling layer 532 may be increased.

At this time, when the first tunneling layer 531 is thin, a hole tunneling may occur. The thinner the first tunneling layer 531, the more likely the hole tunneling may occur. In some embodiments, the thickness of the first tunneling layer 531 may be about 20 nm or less. When the thickness of the first tunneling layer 531 is about 20 nm or less, the hole tunneling may occur easily. In some embodiments, when the thickness of the first tunneling layer 531 is about 20 nm or less, an ohmic contact may be formed between the collector electrode 210 and the second tunneling layer 532.

In some embodiments, the energy band gap of the second tunneling layer 532 may be smaller than the energy band gap of the first semiconductor layer 120. As the second tunneling layer 532 and the first semiconductor layer 120 are in contact with each other, energy band structures of the second tunneling layer 532 and the first semiconductor layer 120 may change so that Fermi levels FL of both are aligned. In some embodiments, as the second tunneling layer 532 and the first semiconductor layer 120 are bonded, a notch in which the valence band VB is sharply and discontinuously bent may be formed between the second tunneling layer 532 and the first semiconductor layer 120. Holes may accumulate in the notch formed in the valence band VB. As the hole density increases, the tunneling probability of the holes may increase. In some embodiments, the notch is formed in the valence band VB at the contact surface between the second tunneling layer 532 including a material having a relatively small energy band gap and the first semiconductor layer 120 including a material having a relatively large energy band gap, and holes accumulated in the notch may be injected into the first semiconductor layer 120 through a quantum tunneling. The second arrow HT2 shown in FIG. 8 indicates the direction of hole tunneling and injection into the first semiconductor layer 120.

A semiconductor device according to some embodiments may include the first tunneling layer 531 of the second conductivity type different from the first conductivity type, and a second tunneling layer 532 of the first conductivity type that includes a semiconductor material having a smaller energy band gap than the first semiconductor layer 120 between the collector electrode 210 and the first semiconductor layer 120. The first tunneling layer 531 may be thinner than the first semiconductor layer 120. The first tunneling layer 531 may be positioned on the collector electrode 210, the second tunneling layer 532 may be positioned on the first tunneling layer 531, and the first semiconductor layer 120 may be positioned on the second tunneling layer 532. As the first tunneling layer 531 and the second tunneling layer 532 are in contact with each other, the hole barrier height increases, so that holes may be injected into the second tunneling layer 532 through tunneling. As the second tunneling layer 532 and the first semiconductor layer 120 are in contact with each other, a valence band VB notch is formed at the contact surface of the second tunneling layer 532 and the first semiconductor layer 120, and holes accumulated in the notch may be injected into the first semiconductor layer 120 through tunneling. Accordingly, even if the first semiconductor layer 120 includes a p-type impurity and includes of a semiconductor material having a larger energy band gap than Si, and the work function of the material forming the collector electrode 210 is not larger than the work function of the material forming the first semiconductor layer 120, the collector electrode 210 and the first semiconductor layer 120 of the semiconductor device according to some embodiments may be in ohmic contact.

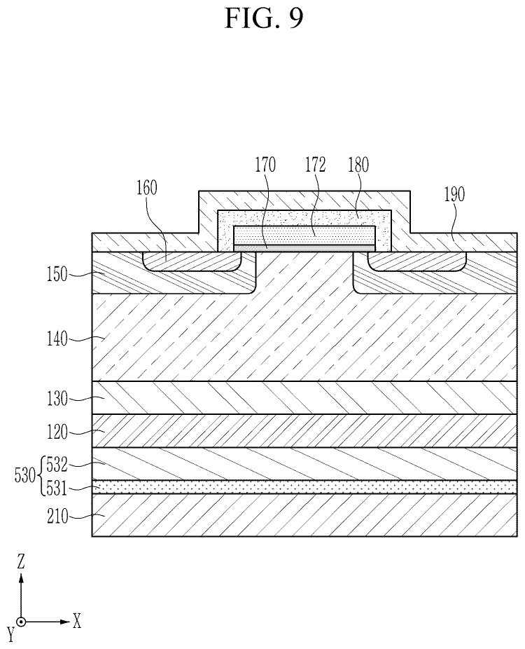

Hereinafter, a modified example of the semiconductor device according to the embodiment of FIG. 7 will be described with reference to FIG. 9.

FIG. 9 is a cross-sectional view of a semiconductor device according to some embodiments. The embodiment illustrated in FIG. 9 may differ from the embodiment illustrated in FIG. 7 only in the structure of the gate insulating layer 170 and the gate electrode 172. In the embodiment illustrated in FIG. 9, the same components as in the embodiment illustrated in FIG. 7 may be referenced with the same drawing reference numerals. For the embodiment illustrated in FIG. 9, the differences from the embodiment illustrated in FIG. 7 will be mainly explained, and any overlapping explanations will be brief or omitted. The embodiment illustrated in FIG. 9 may be a modified version of the embodiment illustrated in FIG. 7, in which only the structures of the gate insulating layer 170 and the gate electrode 172 are modified to be the same as those illustrated in FIG. 3. The structure of the gate insulating layer 170 and the gate electrode 172 in the embodiment illustrated in FIG. 9 may be applied identically or similarly to the description referring to FIG. 3.

Referring to FIG. 9, the gate insulating layer 170 and the gate electrode 172 of a semiconductor device according to some embodiments may be positioned on the upper surface of the second semiconductor layer 140, the upper surface of the first well region 150, and the upper surface of the second well region 160. The gate insulating layer 170 may cover a portion of the upper surface of the first well region 150 and a portion of the upper surface of the second well region 160. The gate insulating layer 170 may cover the upper surface of the second semiconductor layer 140 located between the first well regions 150 spaced apart in the first direction X. The lower surface of the gate electrode 172 may be covered by the gate insulating layer 170. The gate electrode 172 may be spaced apart and insulated from the upper surface of the second semiconductor layer 140, the upper surface of the first well region 150, and the upper surface of the second well region 160 by the gate insulating layer 170.

In some embodiments, the gate electrode 172 may overlap the second semiconductor layer 140, the first well region 150, and the second well region 160 in the third direction Z. Unlike the embodiment illustrated in FIG. 4, the gate electrode 172 may not overlap the second semiconductor layer 140, the first well region 150, and the second well region 160 in the first direction X.

In some embodiments, the lower surface of the gate electrode 172 may be located at a higher level than the upper surface of the first well region 150 and the upper surface of the second well region 160.

In the embodiment illustrated in FIG. 7, the gate insulating layer 170 and the gate electrode 172 may be embedded in an upper portion of the second semiconductor layer 140. On the other hand, in the embodiment illustrated in FIG. 9, the gate insulating layer 170 and the gate electrode 172 may be positioned above the second semiconductor layer 140.

In the embodiment illustrated in FIG. 7, the protective layer 180 may cover the upper surface of the gate insulating layer 170 and the gate electrode 172. In the embodiment illustrated in FIG. 9, the protective layer 180 may further cover the side surfaces of the gate insulating layer 170 and the gate electrode 172.

A semiconductor device according to some embodiments may include the first tunneling layer 531 of the second conductivity type and the second tunneling layer 532 of the first conductivity type between the collector electrode 210 and the first semiconductor layer 120 of the first conductivity type. The first tunneling layer 531 may be positioned on the collector electrode 210, the second tunneling layer 532 may be positioned on the first tunneling layer 531, and the first semiconductor layer 120 may be positioned on the second tunneling layer 532.

In some embodiments, the first tunneling layer 531 may be thinner than the first semiconductor layer 120. The thinner the first tunneling layer 531, the more likely the tunneling may occur. In some embodiments, the thickness of the first tunneling layer 531 may be about 20 nm or less.

In some embodiments, the second tunneling layer 532 may include a semiconductor material having a smaller energy band gap than the first semiconductor layer 120. The second tunneling layer 532 may include a semiconductor material having a smaller energy band gap than the first tunneling layer 531.

As the first tunneling layer 531 and the second tunneling layer 532 are in contact with each other, the hole barrier height increases, so that holes may be injected into the second tunneling layer 532 through tunneling. As the second tunneling layer 532 and the first semiconductor layer 120 are in contact with each other, a valence band VB notch is formed at the bonding surface of the second tunneling layer 532 and the first semiconductor layer 120, and holes accumulated in the notch may be injected into the first semiconductor layer 120 through tunneling. Accordingly, even if the first semiconductor layer 120 includes a p-type impurity and includes a semiconductor material having a larger energy band gap than Si, and the work function of the material forming the collector electrode 210 is not larger than the work function of the material forming the first semiconductor layer 120, the collector electrode 210 and the first semiconductor layer 120 of the semiconductor device according to some embodiments may be in ohmic contact.

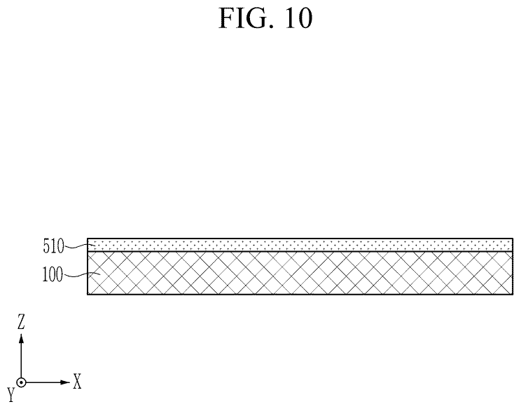

Hereinafter, a method for manufacturing a semiconductor device according to the embodiment of FIG. 1 will be described with reference to FIGS. 10 to 15.

FIGS. 10 to 15 are cross-sectional views showing a manufacturing process of a semiconductor device according to some embodiments.

Referring to FIG. 10, a tunneling layer 510 may be formed on a substrate 100.

In some embodiments, the substrate 100 may be a semiconductor substrate comprising SiC. For example, the substrate 100 may be made of a 4H SiC substrate. In some cases, the substrate 100 may be made of a 3C SiC substrate, a 6H SiC substrate, etc. The substrate 100 may have a second conductivity type. The substrate 100 may be doped with the second conductivity type. The second conductivity type may be, but is not limited to, n-type. The resistivity of the substrate 100 may be about 0.005 Ωcm or more and about 0.035 Ωcm or less. The thickness of the substrate 100 may be about 10 μm or more and about 700 μm or less. The material, doping type, doping concentration, resistivity, thickness, etc. of the substrate 100 are not limited thereto and may be changed in various ways.

The tunneling layer 510 may be formed on the first surface 100a of the substrate 100. The lower surface of the tunneling layer 510 may be in contact with the first surface 100a of the substrate 100. However, it is not limited thereto, and another layer may be additionally positioned between the substrate 100 and the tunneling layer 510. The tunneling layer 510 may be an epitaxial layer formed from a substrate 100 through an epitaxial growth process.

In some embodiments, the tunneling layer 510 may include SiC. For example, the tunneling layer 510 may include 4H SiC. The tunneling layer 510 may have the second conductivity type. The tunneling layer 510 may be heavily doped with the second conductivity type. The second conductivity type may be n-type. A doping concentration of the tunneling layer 510 may be higher than the doping concentration of the substrate 100. In some embodiments, the doping concentration of the tunneling layer 510 may be greater than or equal to about 1*10¹⁹ cm⁻³ and less than or equal to about 5*10²¹ cm⁻³. Preferably, the doping concentration of the tunneling layer 510 may be about 1*10²⁰ cm⁻³ or more and about 1*10²¹ cm⁻³ or less.

In some embodiments, a thickness of the tunneling layer 510 may be less than or equal to about 20 nm.

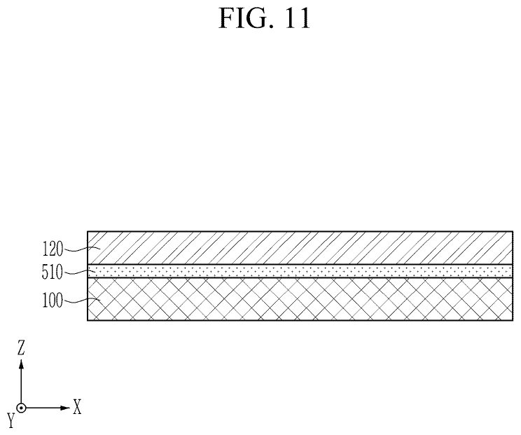

Referring to FIG. 11, a first semiconductor layer 120 may be formed on the tunneling layer 510.

The first semiconductor layer 120 may be formed on the upper surface of the tunneling layer 510. The lower surface of the first semiconductor layer 120 may be in contact with the upper surface of the tunneling layer 510. The first semiconductor layer 120 may be an epitaxial layer formed from the first tunneling layer 510 through an epitaxial growth process.

In some embodiments, the first semiconductor layer 120 may include SiC. For example, the first semiconductor layer 120 may include 4H—SiC. The first semiconductor layer 120 may have a first conductivity type. The first semiconductor layer 120 may be heavily doped with the first conductive type. The first conductivity type could be p-type.

According to the embodiment illustrated in FIGS. 10 and 11, the tunneling layer 510 of FIG. 1 may be formed between the substrate 100 and the first semiconductor layer 120, but is not limited thereto.

For example, the tunneling layer 520 of FIG. 4 may be formed between the substrate 100 and the first semiconductor layer 120 using the same process. In the process of FIG. 10, a first tunneling layer 521 and a second tunneling layer 522 having the same conductivity as the first semiconductor layer 120 may be formed. The first tunneling layer 521 may be formed on the substrate 100, and the second tunneling layer 522 may be formed on the first tunneling layer 521. The first tunneling layer 521 may include a material having a smaller energy band gap than the first semiconductor layer 120 and the second tunneling layer 522. The second tunneling layer 522 may have a higher doping concentration than the first semiconductor layer 120 and the first tunneling layer 521.

As another example, the tunneling layer 530 of FIG. 7 may be formed between the substrate 100 and the first semiconductor layer 120 using the same process. In the process of FIG. 10, a first tunneling layer 531 having a different conductivity type from the first semiconductor layer 120 and a second tunneling layer 532 having the same conductivity type as the first semiconductor layer 120 may be formed. The first tunneling layer 531 may be formed on the substrate 100, and the second tunneling layer 532 may be formed on the first tunneling layer 521. The first tunneling layer 531 may be thinner than the first semiconductor layer 120. A thickness of the first tunneling layer 531 may be about 20 nm or less. The second tunneling layer 532 may include a material having a smaller energy band gap than the first semiconductor layer 120.

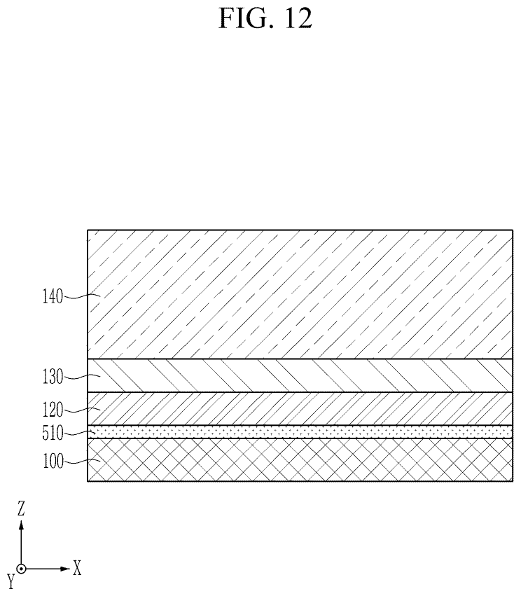

Referring to FIG. 12, a third semiconductor layer 130 and a second semiconductor layer 140 may be formed on the first semiconductor layer 120.

The third semiconductor layer 130 may be formed on the upper surface of the first semiconductor layer 120. The lower surface of the third semiconductor layer 130 may be in contact with the upper surface of the first semiconductor layer 120. The third semiconductor layer 130 may be an epitaxial layer formed from the first semiconductor layer 120 through an epitaxial growth process.

Next, the second semiconductor layer 140 may be formed on the upper surface of the third semiconductor layer 130. The lower surface of the second semiconductor layer 140 may be in contact with the upper surface of the third semiconductor layer 130. The second semiconductor layer 140 may be an epitaxial layer formed from the third semiconductor layer 130 through an epitaxial growth process.

In some embodiments, the third semiconductor layer 130 and the second semiconductor layer 140 may include SiC. For example, the third semiconductor layer 130 and the second semiconductor layer 140 may include 4H SiC. The third semiconductor layer 130 and the second semiconductor layer 140 may have the second conductivity type. The third semiconductor layer 130 may be heavily doped with the second conductive type. The second semiconductor layer 140 may be lightly doped with the second conductive type. The second conductivity type may be n-type.

In some embodiments, a doping concentration of the second semiconductor layer 140 may be greater than or equal to about 1*10¹⁴ cm⁻³ and less than or equal to about 1*10¹⁷ cm⁻³. A thickness of the second semiconductor layer 140 may be about 1 μm or more and about 13 μm or less. The doping concentration, thickness, etc. of the second semiconductor layer 140 are not limited thereto and may be changed in various ways.

In some embodiments, a doping concentration of the third semiconductor layer 130 may be higher than the doping concentration of the second semiconductor layer 140. For example, the third semiconductor layer 130 may be a buffer layer. A semiconductor device according to some embodiments may improve switching speed and reduce on-resistance by including a buffer layer. According to some embodiments, a semiconductor device including a buffer layer may be a punch through IGBT.

However, it is not limited to the embodiment illustrated in FIG. 12. For example, the third semiconductor layer 130 may be omitted. For example, the second semiconductor layer 140 may be positioned directly on the first semiconductor layer 120. A semiconductor device according to some embodiments has improved voltage blocking capability and may operate stably even at high temperatures by omitting a buffer layer. According to some embodiments of the present disclosure, a semiconductor device without a buffer layer may be a non-punch through IGBT.

As another example, the third semiconductor layer 130 may be a field stop layer. A semiconductor device according to some embodiments may have the advantages of both a punch through IGBT and a non-punch through IGBT by including a field stop layer. For example, a semiconductor device according to some embodiments may provide low on-resistance and fast switching speed, and high voltage blocking capability and high temperature stability by including the field stop layer. A semiconductor device according to some embodiments including the field stop layer may be a field stop IGBT.

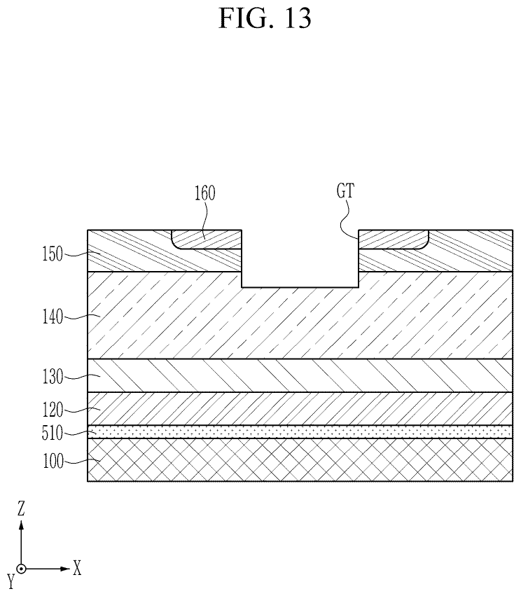

Referring to FIG. 13, a first well region 150 and a second well region 160 may be formed within the second semiconductor layer 140. The first well region 150 and the second well region 160 may be doped regions formed through an ion implantation process within the second semiconductor layer 140. The first well region 150 may be of the first conductivity type, and the second well region 160 may be of the second conductivity type. The first conductivity type may be p-type, and the second conductivity type may be n-type.

In some embodiments, a doping concentration of the first well region 150 may be lower than a doping concentration of the first semiconductor layer 120. The doping concentration of the first well region 150 may be about 1*10¹⁷ cm⁻³ or more and about 1*10¹⁹ cm⁻³ or less. A thickness of the first well region 150 may be about 0.3 μm or more and about 1.1 μm or less. The doping concentration, thickness, etc. of the first well region 150 are not limited thereto and may be changed in various ways.

In some embodiments, the doping concentration of the second well region 160 may be higher than the doping concentration of the second semiconductor layer 140. The doping concentration of the second well region 160 may be about 1*10¹⁷ cm⁻³ or more and about 5*10²⁰ cm⁻³ or less. A thickness of the second well region 160 may be about 0.1 μm or more and about 0.5 μm or less. The doping concentration, thickness, etc. of the second well region 160 are not limited thereto and may be changed in various ways.

Next, a gate trench GT may be formed on the second semiconductor layer 140, the first well region 150, and the second well region 160. The gate trench GT may be formed by patterning the second semiconductor layer 140, the first well region 150, and the second well region 160 through a photo and etching process.

The gate trench GT may be formed to a predetermined depth. The depth of the gate trench GT along the third direction Z may be greater than the thickness of the first well region 150 along the third direction Z and the thickness of the second well region 160 along the third direction Z.

The bottom surface of the gate trench GT may be formed of the second semiconductor layer 140. The sidewall of the gate trench GT may be formed by a side surface of the second semiconductor layer 140, a side surface of the first well region 150, and a side surface of the second well region 160.

As the gate trench GT formed, the first well region 150 and the second well region 160 may be separated in the first direction X, thereby forming a plurality of first well regions 150 and a plurality of second well regions 160. The plurality of first well regions 150 may be spaced apart from each other in the first direction X by the gate trench GT. The plurality of second well regions 160 may be spaced apart from each other in the first direction X by the gate trench GT.

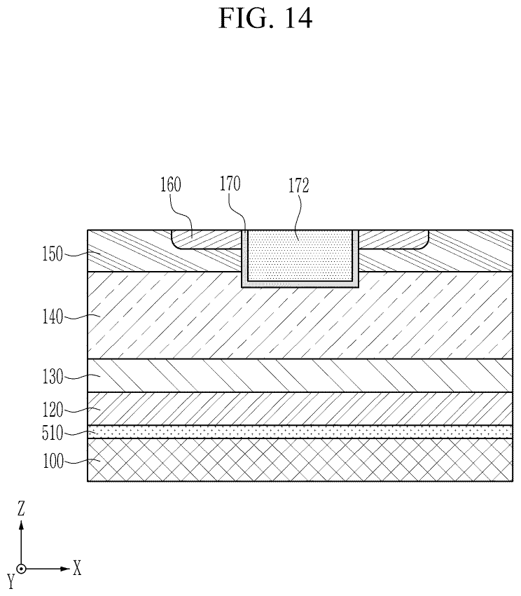

Referring to FIG. 14, a gate insulating layer 170 and a gate electrode 172 may be formed within the gate trench GT. The gate insulating layer 170 may be formed on the bottom surface and sidewalls of the gate trench GT, and the gate electrode 172 may be formed on the gate insulating layer 170.

For example, a gate insulating material layer may be deposited on the bottom surface and sidewalls of the gate trench GT through a deposition process, and a gate electrode material layer may be deposited on the gate insulating material layer. Next, a portion of the gate insulating material layer and the gate electrode material layer covering the upper surfaces of the first well region 150 and the second well region 160 may be removed through an etching process, but is not limited thereto.

The gate insulating layer 170 may conformally cover the bottom surface and side walls of the gate trench GT. The gate electrode 172 may fill the space remaining after the gate insulating layer 170 is formed within the gate trench GT. The gate electrode 172 may be surrounded by the gate insulating layer 170. The gate electrode 172 may be spaced apart from the second semiconductor layer 140, the first well region 150, and the second well region 160 by a gate insulating layer 170.

The upper surface of the gate electrode 172 may be positioned at substantially the same level as the upper surface of the first well region 150 and the upper surface of the second well region 160, but is not limited thereto. For example, the upper surface of the gate electrode 172 may be located at a lower level than the upper surface of the first well region 150 and the upper surface of the second well region 160.

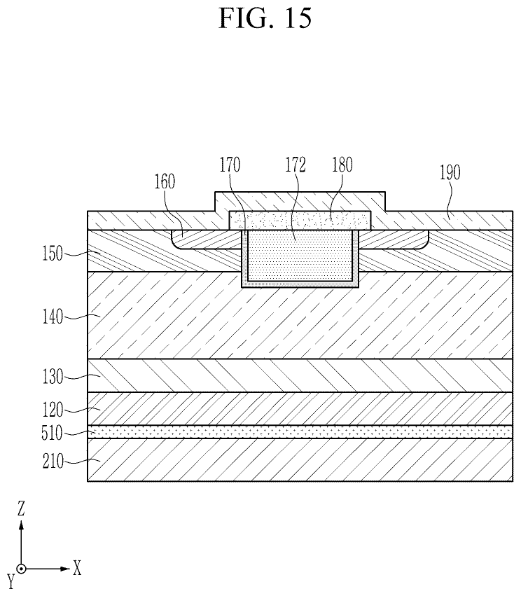

Referring to FIG. 15, a protective layer 180 may be formed on the gate insulating layer 170 and the gate electrode 172, and an emitter electrode 190 may be formed on the first well region 150 and the second well region 160.

The protective layer 180 may cover the upper surface of the gate insulating layer 170 and the gate electrode 172. The protective layer 180 may further cover a portion of the second well region 160 adjacent to the gate electrode 172.

The protective layer 180 may include an insulating material. For example, the protective layer 180 may include, but is not limited to, silicon oxide, silicon phosphate, silicon nitride, silicon oxynitride, or a combination thereof. The protective layer 180 may be composed of a single layer or a plurality of layers.

The emitter electrode 190 may cover the upper surfaces of the first well region 150 and the second well region 160. The emitter electrode 190 may be in contact with the upper surfaces of the first well region 150 and the second well region 160. The emitter electrode 190 may further cover the protective layer 180. The emitter electrode 190 may cover the side surface and upper surface of the protective layer 180.

The emitter electrode 190 may include a conductive material. For example, the emitter electrode 190 may include a metal, an alloy, a conductive metal nitride, a metal silicide, a doped semiconductor material, a conductive metal oxide, a conductive metal oxynitride, or a combination thereof. The emitter electrode 190 is titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC—N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but is not limited thereto. The emitter electrode 190 may be formed of a single layer or the plurality of layers.

Next, the substrate 100 may be removed, and a collector electrode 210 may be formed on a surface opposite to the surface of the tunneling layer 510 facing the first semiconductor layer 120. However, the examples are not limited to this. For example, the substrate 100 may be left without being removed. In this case, the tunneling layer 510 may be positioned on one surface of the substrate 100, and the collector electrode 210 may be positioned on the other surface of the substrate 100.

The collector electrode 210 may include a conductive material. For example, the emitter electrode 190 may include a metal, an alloy, a conductive metal nitride, a metal silicide, a doped semiconductor material, a conductive metal oxide, a conductive metal oxynitride, or a combination thereof. In some embodiments, the collector electrode 210 may include, but is not limited to, the same material as the emitter electrode 190. The collector electrode 210 may be formed of a single layer or a plurality of layers.

According to implementations of the disclosure, a method for manufacturing a semiconductor device includes the steps of forming a first tunneling layer on a first surface of a substrate, forming a first semiconductor layer on the first tunneling layer, forming a second semiconductor layer on the first semiconductor layer, forming a first well region and a second well region in the second semiconductor layer, patterning the second semiconductor layer, the first well region, and the second well region to form a gate trench, forming a gate insulating layer and a gate electrode in the gate trench, forming a protective layer on the gate insulating layer and the gate electrode, forming an emitter electrode on the first well region and the second well region, and forming a collector electrode on an opposite surface of a surface of the first tunneling layer facing the first semiconductor layer. The first semiconductor layer and the first well region are of a first conductivity type, and the second semiconductor layer and the second well region are of a second conductivity type.

The first tunneling layer may be of a second conductivity type different from the first semiconductor layer and may be thinner than the first semiconductor layer.

A thickness of the first tunneling layer may be 20 nm or less.

A doping concentration of the first tunneling layer may be higher than a doping concentration of the second semiconductor layer.

The method for manufacturing the semiconductor device may further include a step of forming a second tunneling layer positioned between the first tunneling layer and the first semiconductor layer.

The method for manufacturing the semiconductor device further includes a step of forming a second tunneling layer positioned between the first tunneling layer and the first semiconductor layer, wherein the first tunneling layer and the second tunneling layer have the same first conductivity type as the first semiconductor layer, and an energy band gap of the first tunneling layer may be smaller than an energy band gap of the second tunneling layer.

The second tunneling layer may have the same first conductivity type as the first semiconductor layer, and an energy band gap of the second tunneling layer may be smaller than an energy band gap of the first semiconductor layer.

The first semiconductor layer and the second tunneling layer include Si and C, and the second tunneling layer may further include an element other than Si and C.

The first semiconductor layer and the second tunneling layer include Si and C, and a Si content (at %) of the second tunneling layer may be higher than a Si content (at %) of the first semiconductor layer.

The energy band gap of the second tunneling layer may be smaller than an energy band gap of the first tunneling layer.

A doping concentration of the second tunneling layer may be higher than a doping concentration of the first tunneling layer.

The doping concentration of the second tunneling layer may be higher than a doping concentration of the first semiconductor layer.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A semiconductor device comprising:
a collector electrode,
a first semiconductor layer of a first conductivity type, a second semiconductor layer of a second conductivity type, a first well region of the first conductivity type, and a second well region of the second conductivity type, wherein the first semiconductor layer, the second semiconductor layer, the first well region, and the second well region are stacked on the collector electrode,
an emitter electrode on the second well region,
a gate electrode adjacent to the first well region,
a gate insulating layer between the gate electrode and the first well region, and
a first tunneling layer between the collector electrode and the first semiconductor layer,
wherein the first tunneling layer is a semiconductor layer of the second conductive type and is thinner than the first semiconductor layer.

2. The device of claim 1,
wherein a doping concentration of the first tunneling layer is higher than a doping concentration of the second semiconductor layer.

3. The device of claim 1, comprising
a second tunneling layer of the first conductive type between the first tunneling layer and the first semiconductor layer,
wherein the second tunneling layer includes a semiconductor material having a smaller energy band gap than the first semiconductor layer.

4. The device of claim 3,
wherein the first tunneling layer includes a semiconductor material having a larger energy band gap than the second tunneling layer.

5. The device of claim 3,
wherein each of the first semiconductor layer and the second tunneling layer includes Si and C.

6. The device of claim 3,
wherein each of the first semiconductor layer and the second tunneling layer includes Si and C,
wherein an atomic concentration of Si in the second tunneling layer is higher than an atomic concentration of Si in the first semiconductor layer.

7. The device of claim 3,
wherein each of the first semiconductor layer and the second tunneling layer includes Ga and N.

8. The device of claim 1,
wherein the first conductivity type is p-type and the second conductivity type is n-type.

9. The device of claim 1, comprising
a plurality of first well regions spaced apart in a first direction, and
a plurality of second well regions spaced apart in the first direction,
wherein a gate trench is between the plurality of first well regions and between the plurality of second well regions,
wherein the gate electrode and the gate insulating layer are within the gate trench.

10. The device of claim 1, comprising
a plurality of first well regions spaced apart in a first direction, and
a plurality of second well regions spaced apart in the first direction,
wherein the gate insulating layer and the gate electrode are on an upper surface of at least a portion of the second semiconductor layer, wherein the at least a portion of second semiconductor layer is between the plurality of first well regions and between the plurality of second well regions.

11. The device of claim 1, comprising
a third semiconductor layer of the second conductive type between the first semiconductor layer and the second semiconductor layer,
wherein a doping concentration of the third semiconductor layer is higher than a doping concentration of the second semiconductor layer.

12. A semiconductor device comprising:
a collector electrode,
a first semiconductor layer of a first conductivity type, a second semiconductor layer of a second conductivity type, a first well region of the first conductivity type, and a second well region of the second conductivity type, wherein the first semiconductor layer, the second semiconductor layer, the first well region, and the second well region are stacked on the collector electrode,
an emitter electrode on the second well region,
a gate electrode adjacent to the first well region,
a gate insulating layer between the gate electrode and the first well region, and
a first tunneling layer between the collector electrode and the first semiconductor layer,
wherein the first tunneling layer is a semiconductor layer of the first conductive type and includes a semiconductor material having a smaller energy band gap than a semiconductor material of the first semiconductor layer.

13. The device of claim 12, comprising
a second tunneling layer of the first conductive type between the first tunneling layer and the first semiconductor layer,
wherein the second tunneling layer includes a semiconductor material having a larger energy band gap than the first tunneling layer.

14. The device of claim 13,
wherein a doping concentration of the second tunneling layer is higher than a doping concentration of the first tunneling layer.

15. The device of claim 12, comprising
a second tunneling layer of the second conductive type between the collector electrode and the first tunneling layer,
wherein the second tunneling layer includes a semiconductor material having a larger energy band gap than the first tunneling layer.

16. The device of claim 15,
wherein the second tunneling layer is thinner than the first semiconductor layer.

17. The device of claim 16,
wherein a doping concentration of the second tunneling layer is higher than a doping concentration of the second semiconductor layer.

18. A semiconductor device comprising:
a collector electrode,
a first semiconductor layer of a first conductivity type, a second semiconductor layer of a second conductivity type, a first well region of the first conductivity type, and a second well region of the second conductivity type, wherein the first semiconductor layer, the second semiconductor layer, the first well region, and the second well region are stacked on the collector electrode,
an emitter electrode on the second well region,
a gate electrode adjacent to the first well region,
a gate insulating layer between the gate electrode and the first well region, and
a first tunneling layer and a second tunneling layer between the collector electrode and the first semiconductor layer,
wherein the first tunneling layer is on the collector electrode, the second tunneling layer is on the first tunneling layer, and the first semiconductor layer is on the second tunneling layer,
wherein an energy band gap of the first tunneling layer and an energy band gap of the second tunneling layer are different.

19. The device of claim 18,
wherein each of the first tunneling layer and the second tunneling layer is of the first conductivity type, and
wherein an energy band gap of the first tunneling layer is smaller than an energy band gap of the second tunneling layer.

20. The device of claim 18,
wherein the first tunneling layer is of the second conductivity type, and the second tunneling layer is of the first conductivity type,
wherein the first tunneling layer is thinner than the first semiconductor layer, and
wherein an energy band gap of the second tunneling layer is smaller than an energy band gap of the first semiconductor layer.
